(19) United States
(12) Patent Application Publication
(10) Pub. No.: US 2011/0062420 A1
(43) Pub. Date: Mar. 17, 2011

(54) Quantum well thermoelectric module

(75) Inventors: Saeid Ghamaty, La Jolla, CA (US); Norbert B. Elsner, La Jolla, CA (US); Aleksandr Kushch, Poway, CA (US); Daniel J. Krommenhoek, Wake Forest, NC (US); Frederick A. Leavitt, San Diego, CA (US)

(73) Assignee: Hi-Z Technology Inc

(21) Appl. No.: 12/806,359

(22) Filed: Aug. 11, 2010

Related U.S. Application Data
(63) Continuation-in-part of application No. 12/460,424, filed on Jul. 17, 2009.

(51) Int. Cl. H01L 29/66; B82Y 99/00

(52) U.S. Cl. 257/28; 257/E29.168; 977/955

(57) ABSTRACT

Quantum well thermoelectric modules and a low-cost method of mass producing the modules. The devices are comprised of n-legs and p-legs, each leg being comprised of layers of quantum well material in the form of very thin alternating layers. In the n-legs the alternating layers are layers of n-type semiconductor material and electrical insulating material. In the p-legs the alternating layers are layers of p-type semiconductor material and electrical insulating material. Both n-legs and p-legs are comprised of materials providing similar thermal expansion. In preferred embodiments the layers, referred to as super-lattice layers are about 4 nm to 20 nm thick. The layers of quantum well material is separated by much larger layers of thermal and electrical insulating material such that the volume of insulating material in each leg is at least 20 times larger than the volume of quantum well material.

### CROSS REFERENCE TO RELATED APPLICATIONS

The present invention is a continuation-in-part of Ser. No. 12/460,424 filed Jul. 17, 2009 which is incorporated herein by reference.

### FIELD OF THE INVENTION

The present invention relates to thermoelectric modules and in particular to low-cost, high-temperature high-efficiency quantum well modules.

### BACKGROUND OF THE INVENTION

### Thermoelectric Materials

The Seebeck coefficient of a bulk thermoelectric material is defined as the open circuit voltage produced between two points on a conductor, where a uniform temperature difference of 1 K exists between those points. The figure-of-merit Z of a thermoelectric material is defined as:

Z=α²/ρκ

where α is the Seebeck coefficient of the material, ρ is the electrical resistivity of the material and κ is the thermal conductivity of the material. A dimensionless figure of merit is found by multiplying Z by an average temperature. Greater values of ZT indicate greater efficiency of the thermoelectric material.

A large number of semiconductor materials were being investigated by the late 1950's and early 1960's, several of which emerged with Z values significantly higher than similar values for metals or metal alloys. No single compound semiconductor evolved that exhibited a uniform high figure-of-merit over a wide temperature range, so research focused on developing materials with high figure-of-merit values over relatively narrow temperature ranges. Of the great number of materials investigated, those based on bismuth telluride, lead telluride and silicon-germanium alloys emerged as the best for operating in various temperature ranges. Much research has been done to improve the thermoelectric properties of the above three thermoelectric materials. For example n-type bismuth telluride, Bi₂Te₃ typically contains 5 to 15 mol percent Bi₂Se₃ and p-type Bi₂Te₃ typically contains 70-90 mol percent Sb₂Te₃. Lead telluride is typically doped with sodium for P type and iodine (PbI₂) for N type.

### Thermoelectric Modules

Electric power generating thermoelectric modules are well known. These modules typically are comprised of a number of thermoelectric elements called n-legs and p-legs connected electrically in series. The effect is that a voltage differential of a few millivolts is created in the presence of a temperature difference at the two junctions of p-type thermoelectric semiconductor elements and n-type thermoelectric semiconductor elements. Since the voltage differential is normally small, many of these elements (such as about 100 elements) are typically positioned in parallel between a hot surface and a cold surface and are connected electrically in series to produce potentials of a few volts. Electrons flow from the hot side to the cold side through the n-legs and from the cold side to the hot side through the p-legs. Many references refer to the current in the p-legs as holes flowing from the hot side to the cold side. These references also refer to current flowing from the cold side to the hot side through the n-legs and from the hot side to the cold side through the p-legs.

### Hi-Z Prior Art Bismuth Telluride Molded Egg-Crate Modules

For example Hi-Z Technology, Inc. offers a Model HZ-14 bismuth telluride thermoelectric module designed to produce about 14 watts at a load potential of 1.66 volts with a 200° C. temperature differential. Its open circuit potential is 3.5 volts. The module contains 49 n-legs and 49 p-legs connected electrically in series. It is a 0.5 cm thick square module with 6.27 cm sides. The legs are p-type and n-type bismuth telluride semiconductor legs and are positioned in an egg-crate type structure that insulates the legs from each other except where they are intentionally connected in series at the top and bottom surfaces of the module. That egg-crate structure which has spaces for 100 legs is described in U.S. Pat. No. 5,875,098 which is hereby incorporated herein by reference. The egg-crate is injection molded in a process described in detail in the patent. This egg-crate has greatly reduced the fabrication cost of these modules and improved performance for reasons explained in the patent. Insulating walls keep the electrons flowing in the desired series circuit. Other Bi₂Te₃ thermoelectric modules that are available at Hi-Z are designed to produce 2.5 watts, 9 watts, 14 watts and 20 watts at the 200° C. temperature differential.

### Temperature Limitations

The egg-crates for the above described Bi₂Te₃ modules are injection molded using a thermoplastic supplied by Dupont under the trade name “Zenite”. Zenite melts at a temperature of about 350° C. The ZT thermoelectric properties of Bi₂Te₃ peak at about 100° C. and are greatly reduced at about 250° C. For both of these reasons, use of these modules are limited to applications where the hot side temperatures are lower than about 250° C. to 300° C.

### Thermoelectric Efficiencies

Despite the fact that there exists a great need for non-polluting electric power and the facts that there exists a very wide variety of un-tapped heat sources, thermoelectric electric power generation in the United States and other countries is minimal as compared to other sources of electric power. The reason primarily is that thermoelectric efficiencies are typically low compared to other technologies for electric power generation and the cost of thermoelectric systems per watt generated is high relative to other power generating sources. Generally the efficiencies of bismuth telluride thermoelectric power generating systems are in the range of about 5 percent. Proposals to increase these efficiencies by segmenting different types of materials have been made but these stacked designs become complicated and expensive to produce and the resulting efficiencies are not much better than about 10 percent.

### Attempts at Improved Performance

Workers in the thermoelectric industry have been attempting to improve performance of thermoelectric devices for the past 20-30 years with some success, but much more is needed. Most of the effort has been directed to reducing the thermal conductivity (κ) without adversely affecting the electrical conductivity. Experiments with super-lattice quantum well materials have been underway for several years.

### Super-Lattice and Quantum Well Defined

A super-lattice is defined as a periodic structure of layers of two (or more) materials, typically with thickness per layer of several nanometers. The layers may be completely amorphous or partially amorphous and partially crystalline or completely crystalline. A quantum well is a potential well that confines particles, (which were originally free to move in three dimensions) to two dimensions, forcing them to occupy a planar region. The effects of quantum confinement take place when the quantum well thickness becomes comparable at the de Broglie wavelength of the carriers (generally electrons and holes). The de Broglie wavelength, λ, is:

λ=h/p

where h is Planks constant and p is the momentum of the particle. For an electron with a velocity of 2.18×10⁶ m/s, the de Broglie wavelength is about 3 Angstroms (0.3 nanometers). For an electron with a velocity of 1×10⁵ m/s, the de Broglie wavelength is about 60 Angstroms (6 nanometers).

These super-lattice quantum well materials were discussed in a paper by Gottfried H. Dohler which was published in the November 1983 issue of Scientific American. This article presents an excellent discussion of the theory of enhanced electric conduction in super-lattices. These super-lattices contain alternating conducting and barrier layers and create quantum wells that improve electrical conductivity. These super-lattice quantum well materials are crystals grown by depositing semiconductors in layers with thicknesses generally less than about 10 nm (100 Angstroms). Thus, each layer is generally less than 100 atoms thick. (These quantum well materials are also discussed in articles by Hicks, et al and Harman published in Proceedings of 1992 1st National Thermoelectric Cooler Conference Center for Night Vision & Electro Optics, U.S. Army, Fort Belvoir, Va. The articles project theoretically very high ZT values as the layers are made progressively thinner.) The idea being that these materials laid down as super-lattices might provide very great increases in electric conductivity without adversely affecting Seebeck coefficient or the thermal conductivity.

The present inventors have actually demonstrated that high ZT values can definitely be achieved with Si/Si_{0.8}Ge_{0.2} super-lattice quantum well n-legs and p-legs (see U.S. Pat. Nos. 5,436,467, 5,550,387, 6,096,964, 6,096,965, 6,914,343, 7,038,234, 7,342,170 and 7,400,050). They have also demonstrated that these very high ZT values can be achieved with super-lattice quantum well modules having Si and SiC n-legs and B₄C and B₉C p-legs (see, for example U.S. Pat. Nos. 6,828,579, 6,914,343 and 7,342,170). Most of the efforts to date with super-lattice quantum well material have involved alloys that are known to be good thermoelectric materials, many of which are difficult to manufacture as extremely thin layers. The present inventors have had issued to them United States patents which disclose such materials and explain how to make them. These patents (which are hereby incorporated by reference herein) include U.S. Pat. Nos. 5,436,467; 5,550,387; 6,096,964; 6,096,965; 7,038,234 and 7,342,170. The '234 patent describes n-legs utilizing Si and SiGe layers and p-legs utilizing B₄C and B₉C layers. The '170 patent discloses similar legs in which the n-legs utilize Si and SiC layers with the p-legs also utilizing B₄C and B₉C layers. A large number of very thin layers (in the '234 patent, more than 3 million layers per leg) together produce a thermoelectric leg about 0.4 cm thick. In the embodiment shown in the figures all the legs are connected electrically in series and otherwise are insulated from each other in an egg-crate type thermoelectric element as indicated in FIG. 3A. As shown in FIG. 3B electrons flow from the cold side to the hot side through p-legs and from the hot side to the cold side through n-legs. (Current is generally considered in most current thermoelectric texts to flow in a direction opposite electron flow; i.e. from cold to hot through the n-legs and hot to cold through the p-legs.)

### Costs to Be Competitive

For thermoelectric modules of the type described above in order to be generally competitive with other power generating methods must be made at costs in the range of about $1.00 per watt with efficiencies in the range of 20 to 30 percent or greater. Prior art thermoelectric devices with legs made of bulk materials cost at least several dollars per watt. In addition, the efficiencies of the thermoelectric devices with bulk material legs are in the range of about 5 percent. In general the costs of products that are mass produced tend to gravitate toward the cost of the materials from which they are made. Germanium differs from silicon in that the supply of silicon is limited only by production facilities whereas germanium availability is limited by the resource. As a result silicon could be purchased in 1998 for less than $10/kg, but the price of germanium was then $800/kg. In 2008 the price of germanium had increased to $1,400/kg. Recently the prices of both silicon and germanium have fallen due to the current economic recession.

What is needed is a method of making quantum well thermoelectric modules at costs of less than about $1.00 per watt. With costs in this range and efficiencies in the range of 20 to 30 percent thermoelectric modules could become extremely popular even for large scale electric power production.

### SUMMARY OF THE INVENTION

### Low-Cost N-Legs and P-Legs

The present invention provides quantum well thermoelectric modules with quantum well n-legs and p-legs and a low cost method of mass producing the modules. The n-legs and p-legs are each comprised of layers of quantum well material in the form of very thin alternating layers of high-temperature thermoelectric semiconductor materials having different band-gaps. Applicants have recently discovered after years of work on super-lattice materials, that the super-lattices combined with a very large number of potential dopants, provide Applicants the opportunity to create a huge variety of new thermoelectric materials which can be (in effect) made-to-order. In preferred embodiments the super-lattice materials are silicon and silicon carbide and in other preferred embodiments the materials are poly-types of boron carbide. Applicants believe also that silicon/silicon nitride n-legs and p-legs can be fabricated as very high-temperature thermoelectric materials. In preferred embodiments to improve the efficiency and lower the module cost the legs also include layers of low cost electrical and thermal insulating material. In some of these preferred embodiments these insulating layers may be substrates on which the quantum well super-lattice layers are deposited.

### Silicon Carbide N-Legs and P-Legs

Applicants have built, tested and patented quantum well super-lattice prototype samples with silicon carbide and silicon n-legs. (See U.S. Pat. No. 6,828,579, Thermoelectric Devices with Si/SiC Superlattice N-Legs.) In the parent application (Ser. No. 12/460,424) Applicants disclose techniques for making low cost modules with silicon and silicon carbide n-legs. The module specifically described in that patent utilized boron carbide for the p-legs. These p-legs utilized alternating layers of B₄C and B₉C. The prior art to the best of Applicants' knowledge does not disclose any techniques for making silicon and silicon carbide super-lattice p-legs. However Applicants have now discovered techniques for making thermoelectric quantum well modules with both n-legs and p-legs made using silicon and silicon carbide super-lattice layers. Applicants have determined that having both n-legs and p-legs made from the same materials is advantageous in that many problems associated with differential thermal expansion and contraction are avoided.

In a special preferred embodiment utilizing super-lattice n-legs, the super-lattice layers of the p-legs are comprised of alternating layers of n-doped silicon carbide and p-doped silicon. In one of these embodiments, actually fabricated and tested by Applicants, the p-legs of the silicon carbide layers were produced with sputtering targets of silicon carbide lightly doped n-type with nitrogen at about 10¹⁶ to 10¹⁸ atoms per cc and the silicon layers were produced with silicon more heavily doped with boron at about 10²¹ atoms per cc. The n-type SiC layers were 10 nm thick and the p-type Si layers were 4 nm thick. Seebeck coefficient for the resulting super-lattice material was measured at about 985 microvolts per degree centigrade. This compares to 180 microvolts per degree centigrade for prior art p-doped bulk bismuth telluride thermoelectric material. Electrical resistivity for the new super-lattice material was also a substantial improvement over the prior art material; i.e. 0.31 milliohm-centimeter for the p-type super-lattice material as compared to 0.8 milliohm-centimeter for the bismuth telluride. Other techniques for producing p-type silicon-silicon carbide quantum well thermoelectric legs are proposed. In an alternate preferred embodiment, silicon carbide powders are mixed with about one percent aluminum and are hot pressed then heated to 2300° C. to evenly distribute and activate the aluminum dopant to form p-type silicon carbide sputtering targets which are then used with silicon sputtering targets to produce the super-lattice quantum well layers. Boron can be substituted for the aluminum.

Another proposed technique utilizes reactive sputtering. In this case the sputtering target is silicon. To produce the silicon carbide layers the gas mixture is argon and methane (CH₄). To produce the silicon layers, the methane flow is stopped so the gas flow is only argon. The sputtering chamber is maintained at a pressure of about 20 mm of mercury. RF power is controlled within 100 to 200 watts. The composition of the films can be controlled by varying the relative pressures of the argon and the methane. The n and p features of the nano-structured Si/SiC materials can be controlled by proper doping of the Si targets

Silicon carbide films can also be produced by co-sputtering the carbon and the silicon from separate targets at the same time. The n and p dopants are preferably added to the silicon targets. Silicon layers can be applied using the same target used for the co-sputtering of the silicon carbide or if a different dopant concentration is required a separate silicon target must be used. Co-sputtering equipment is available from 4 Wave, Inc.

There exists a wide variety of semiconductor materials that are potentially available for fabrication of quantum well thermoelectric modules. However many of these materials are rare and as a result become expensive when demand is high. Applicants preferred quantum well material for their preferred quantum modules is a one-to-one ratio of silicon and carbon, two of the most abundant materials on earth. With the utilization of these materials costs, over a period of years, should continue to go down as demand goes up.

### Boron Carbide N-Legs and P-Legs

In U.S. Pat. No. 6,828,579 referred to above the p-legs were comprised of alternating layers of B4C and B9C and the n-legs were comprised of silicon carbide and silicon. As explained above Applicants have determined that there are important advantages in having both types of legs comprised of the same basic materials. Therefore, Applicants have disclosed in this specification techniques for making modules with polytypes of boron carbide in both the n-legs and the p-legs.

### Techniques for Making Low-Cost Modules

In preferred embodiments the quantum well material is produced with a sputter process in a web coater on an insulating substrate to produce quantum well film which is stacked with insulating spacers to produce a quantum well stack which is then sliced and diced to produce the quantum well legs. In preferred embodiments layers are about 4 nm to 10 nm thick. In order to reduce costs of the modules, insulating material may be added to the legs. In many applications the insulating material will also improve the efficiencies of the modules. In preferred embodiments, the volume of insulating material in each leg is at least 12 times the volume of quantum well super-lattice layers. In other preferred embodiments the ratio is about 50 which results in a module cost of about $0.85 per watt.

### Web Coating Sputtering Machines

Quantum well material can be deposited with sputtering machines at a rate of about 10 nanometers per minute. A typical thermoelectric module designed in accordance with the present invention may contain only about 0.14 cm³ of the quantum well material. Using a prior art sputtering machines quantum well material could be produced at the rate of about 0.25 cm³ per day. Applicants have performed demonstration runs on a two-target web coating sputtering machine showing that with this prior art machine 1.4 cm³ of quantum well material could be produced per day, enough material per day for about 10 modules of a preferred module design. Applicants have developed a preliminary design of a multiple target web coating machine to produce about 29 cm³ of super-lattice film per day, enough material to produce per day more than 200 modules of the preferred design. Details of a prior art web coating sputtering machine is described in detail in the parent patent application identified above along with designs for modifications that would greatly increase production. These details have been incorporated by reference.

### First Preferred Embodiment

In a first preferred embodiment, 400 quantum well silicon and silicon carbide super-lattice layers are grown on a 200 micron thick substrate in a web coating sputtering machine. The preferred substrate is Kapton coated with a 100 nm buffer layer of silicon. On the silicon buffer layer are deposited alternating 10 nm layers of silicon carbide and silicon. The thickness of the quantum well material on the 200 micron thick substrate is about 8 microns, so the quantum well film and substrate is about 208 microns. The 8 micron film on the 200 micron substrate and a 200 micron spacer are assembled in sets with thicknesses of about 408 microns and the sets are stacked 12 high (12×408 microns) to produce sheets of thermoelectric material about 0.49 cm thick. The stack of quantum well film and spacers is cut into legs with dimensions of about 0.3 cm×0.5 cm×0.49 cm. The legs are treated at both hot and cold ends with an ion implantation procedure and sputter coated at both hot and cold ends with molybdenum and silver to improve electrical connections between the legs. The legs are then assembled into a thermoelectric egg-crate similar to prior art thermoelectric egg-crates as shown in FIGS. 3A and 3B. At the bottom of each leg is complaint cold member 200 comprised of a flexible material such as copper felt. Above complaint cold member 200 is a thin layer of an electrical insulator (not shown) such as Al₂O₃. Above the insulator layer is a thin electrical conductor (preferably copper film that connects n-legs to the p-legs except where the egg-crate spacers 204 separate the legs at the cold side. Each of the n-legs and the p-legs preferably have been treated as described at the bottom and top with ion implantation and sputter coated with molybdenum and/or silver so the bottom of the so treated legs are in contact with the copper film providing excellent electrical contacts. The n-legs N and the p-legs P are all connected in series as shown in FIG. 3B. The hot side (top) of the legs have also been treated with ion implantation and sputter coated with molybdenum and/or silver as described above. The electrical connection between the n-legs and the p-legs at the hot side of the module is provided with iron shoes 206. The use of the iron shoes is preferred in order the avoid any cross contamination of the n-legs and the p-legs. Above the iron shoes is a thin layer of copper film (not shown) added to improve conduction with in the module. At both the hot side and the cold side a thin electrical insulator layer is provided so as to assure a series connection of all of the legs. Arrows 210 show the path of electron flow through the thermoelectric legs. Electrons flow from hot to cold through the n-legs and from cold to hot through the p-legs. Electric current is normally assumed to flow in the opposite direction. Most references refer to electrons flowing from hot to cold through n-legs and holes flowing from hot to cold through the p-legs.

The ratio of insulating material to quantum well material in the legs is about 50. The estimated maximum efficiency of the module is about 21.4 percent. This preferred embodiment is a thermoelectric 10×10 egg crate type module about 5.55 cm×5.55 cm×0.7 cm. The module has 98 active thermoelectric legs, with each leg having more than 4,800 super-lattice quantum well layers. Applicants expect to be able to produce more than two hundred of these modules per day per web coating machine. Applicants expect to manufacture the modules for about $40 per module at a cost per watt of about $0.85/watt or less.

### Other Quantum Well Combinations

Applicants' experiments and research have shown that there is a large number of potential semiconductor super-lattice combinations in addition to the ones referred to above that could result in excellent quantum well thermoelectric properties with proper doping. In this specification Applicants have included lists of potential candidate combinations of these semiconductors.

### Other Substrates and Spacers

Other preferred substrate and spacers include Kapton, glass, silicon-coated glass and porous silicon. Substrates that can be dissolved (i.e. NaCl), evaporated or etched away (metals) can also be used.

### BRIEF DESCRIPTION OF THE DRAWINGS

FIG. 1 shows a high-cost, low volume process for making quantum well thermoelectric materials.

FIGS. 2A and 2B show features of a prior art web coating machine.

FIGS. 3A and 3B show a prior art egg-crate and demonstrates series connection of the thermoelectric legs.

FIG. 4 shows a flow diagram for fabricating a preferred egg-crate thermoelectric module.

FIG. 4A show a section of a thermoelectric quantum well film with 800 quantum well layers on a 200 micron substrate.

FIG. 4B shows a section of a spacer for use with the FIG. 4A film.

FIGS. 4C and 4D show 25 cm² sections of the spacers and the quantum well film alternatingly stacked together.

FIG. 4E shows features of a quantum well leg in accordance with a preferred embodiment.

FIGS. 4F through 4J show magnified portions of the FIG. 4 leg.

FIG. 5 show details of five types of quantum well egg-crate designs.

FIG. 6 shows the effect of annealing super-lattice layers of silicon and silicon-germanium on QW crystallinity and performance (power factor).

FIG. 7 lists band gaps and thermal conductivity of a variety of semiconductor materials.

FIG. 8 lists several potential quantum well combinations

### DETAILED DESCRIPTION OF PREFERRED EMBODIMENTS

### Applicants Earlier Patents

As explained in the Background section, Applicants have disclosed techniques for placing the thin alternating layers on film substrates. In these patents the alternating layers specifically described include layers comprised of silicon and silicon-germanium to produce both n-legs and p-legs. The Si layers were referred to as insulating or barrier layers and the SiGe layers are appropriately doped to produce n legs and p legs and are referred to as conducting layers. Also as described in the Background section Applicants have disclosed how to fabricate silicon and silicon carbide n-legs with p-legs made from different semiconductor materials. Applicants have recently discovered how to fabricate p-legs using heavily p-doped silicon and low cost lightly n-type silicon carbide with excellent results and have proposed other combinations of silicon and silicon carbide which could prove equally effective.

### Super-Lattice Quantum Well Layers

As explained in the Dohler article, in these very thin layers, electrons made available for electrical conduction in the n-doped conduction layer can migrate to the boundary layer to make conduction possible there. Applicants are not certain as to the reason for the excellent electrical conducting properties of these quantum well materials. However their research confirms that these super lattice quantum well layers do produce excellent thermoelectric results including low electrical resistance and increased Seebeck coefficients. These extremely thin films can be varying degrees of amorphous to crystalline and still produce quantum well effects.

### Applicants' Experiments

In 2002 Applicants produced a small test quantum well thermoelectric couple with 11 microns of Si/SiGe thermoelectric layers on a 5-micron silicon film that has operated at 14 percent conversion efficiency. This efficiency was calculated by dividing the power out of the couple by the power in to an electric heater with no correction for extraneous heat losses. The accuracy of the experimental set-up used was validated by measurement of the 5 percent efficiency of a couple fabricated of bulk Bi₂Te₃ alloys.

Measurements at University of California at San Diego on behalf of Applicants indicate that the thermal conductivity of the Si—SiGe multi-layer films are significantly reduced in comparison with the bulk value. The use of the UCSD low value for the in-plane thermal conductivity leads to a factor of three enhancement in the performance (i.e., figure of merit) of the material.

### Fabrication of Quantum Well Thermoelectric Film

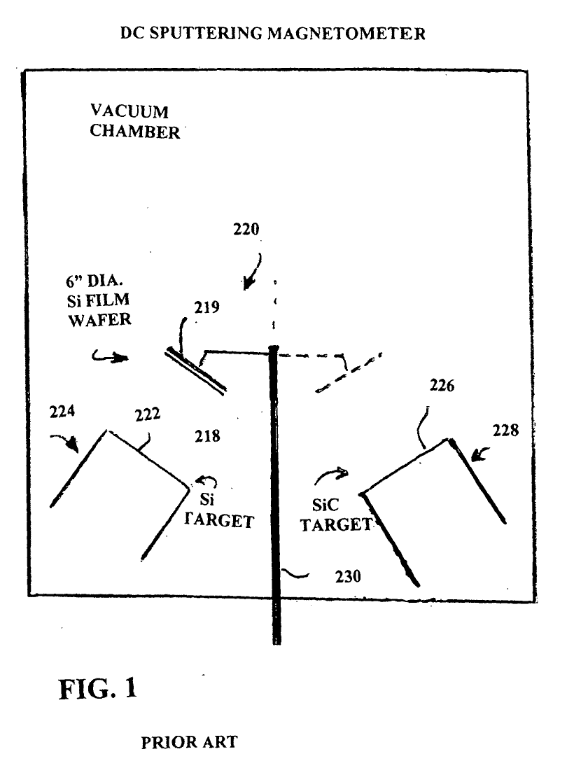

FIG. 1 is a prior art drawing of the primary elements of a DC sputtering magnetometer set up to produce Si/SiC thermoelectric film. A 5-micron thick n-doped silicon wafer which functions as a silicon substrate 218 is placed on a graphite holder 219 as shown at 220 in FIG. 1. A Silicon target 222 is placed on high voltage target holder 224 and a SiC target 226 is placed on high voltage target holder 228. The targets are maintained at 800 volts with a current of about 0.1 amps. The sputtering chamber is a brought to a vacuum of about 15-20 microns of Hg with a pure argon environment. Argon ions bombard the targets releasing target atoms from target 222 that collect on the substrate 218. The substrate 218 was maintained at a temperature of about 375 degrees C. to help balance out stresses that otherwise tend to develop in the deposited film. The sputtering magnetometer is operated so as to deposit 10 nm (0.01 micron) layers on substrate 218 at the rate of about one layer per minute. After the first silicon layer is deposited, substrate holder is pivoted so that substrate 218 is positioned over SiC target 226 and a 10 nm layer of SiC is deposited on top of the 10 nm silicon layer. This process is repeated until a desired number of layers are produced. That system produced thousands of super lattice-layers but the film area was only about 175 square cm. At a rate of 10 nm per minute a volume of thermoelectric material about 0.25 cm³ could be produced per day which is enough material for about one module in accordance with a typical thermoelectric module fabricated in accordance with the first preferred embodiment of the present invention.

### Very Large Area Super-Lattice Films

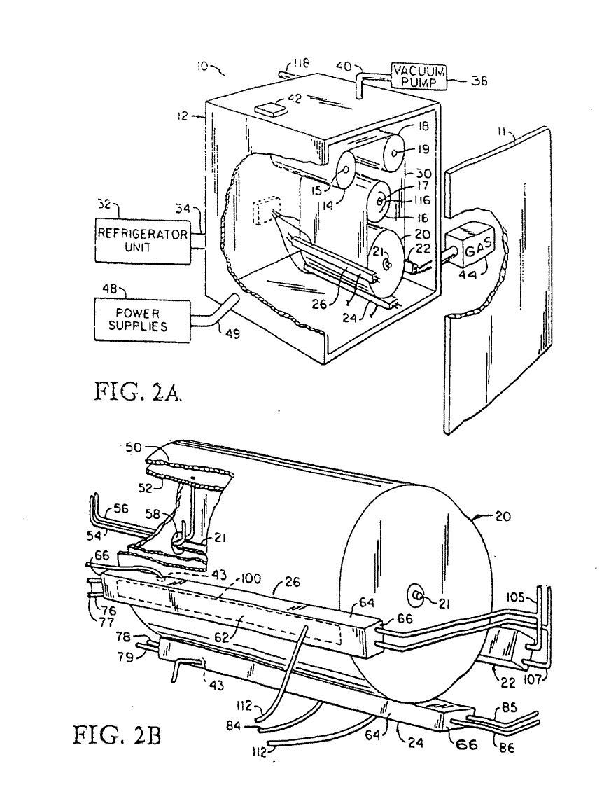

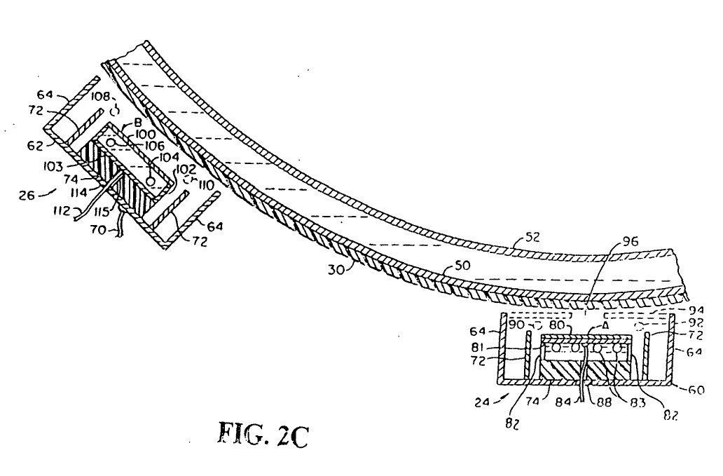

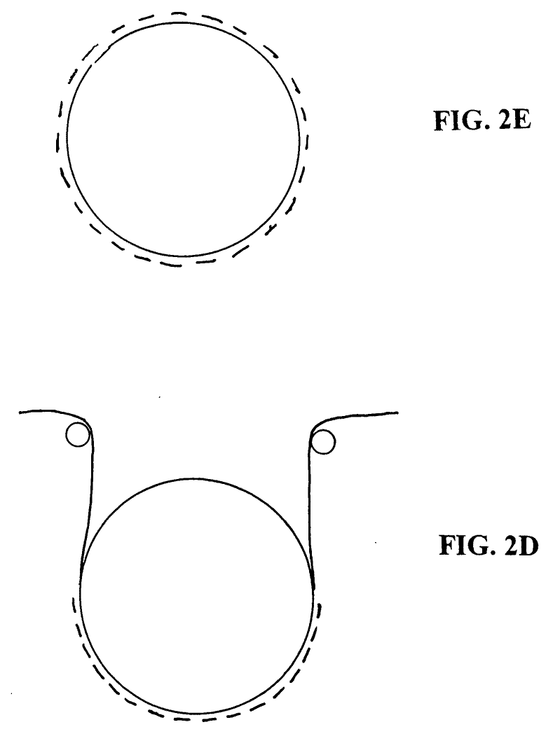

Applicants have now actually demonstrated that with an existing large web coater type sputtering machine similar to the one shown in FIGS. 2A and 2B with only two sputter targets, each 1 meter (100 cm)×5 cm, quantum well material could be deposited at 10 nm per minute. This machine can produce quantum well film volume at a rate of 1.44 cm³ of quantum well material per day. The quantity of thermoelectric material required per module depends on the module design. A preferred design is described in the section below entitled “First Preferred Thermoelectric Module”. This module requires 0.144 cm³ of quantum well material, so the machine described above can produce enough quantum well material for about 10 of these modules per day.

The equipment used was a web coater sputtering machine of the type described in U.S. Pat. No. 4,204,942. FIGS. 2A and 2B are drawings FIGS. 1 and 2 from that patent which is incorporated herein by reference. This web coater sputtering machine comprises three deposition chambers only two of which were used to deposit the super-lattice layers on the substrate film. Each chamber may be provided with a target material to be sputtered onto the substrate. Some details of the web coater extracted from the '942 patent are described in the next section. Additional details are described in parent application Ser. No. 12/460,420. Various procedures for controlling the depositions are described below. In the section Many Target Sputter Machines Applicants have proposed designs for sputter machines with up to forty 500 cm² targets that would increase the quantum well film production by a factor of 20 so that quantum well film for 200 of the typical modules could be produced per day with a single machine.

### Description of Prior Art Web Coater

FIG. 2A illustrates a preferred prior art web coater. The apparatus, generally designated by the reference numeral 10, includes an evacuation chamber 12 with door 11 removed to show mounted interior of the chamber play-out roll 14, take-up roll 16, idler drum 18 and support cylinder 20. The film is fed from play-out roll 14 onto idler drum 18 and taken up on take-up roll 16. The play-out and take-up rolls, as well as idler drum 18, are rotatably mounted to a portion of the chamber 12 via spindles 15, 17 and 19, respectively. Similarly, support cylinder 20 is rotatably mounted to spindle 21. The spindles 15, 17, 19 and 21 are generally horizontally oriented and parallel to one another. Also mounted within the chamber at spaced locations about the outer circumferential surface of the support cylinder 20 are deposition stations 22, 24 and 26.

As illustrated in FIG. 2A, a substrate 30 (typically a long, thin sheet of Kapton) is mounted upon play-out roll 14 and then caused to extend from the play-out roll to take-up roll 16 via idler drum 18 and support cylinder 20, passing through (as will be more particularly shown below) the interstitial space between deposition stations 22, 24 and 26 and support cylinder 20.

Apparatus 10 further includes a refrigeration unit 32 which is communicated to the chamber 12 via a conduit 34 to provide the support cylinder 20 and deposition stations 22-26 with a coolant. For clarity, conduits communicating the coolant to the individual deposition stations are not fully illustrated in the Figures.

A vacuum pump 38 is communicated to chamber 12 via exhaust conduit 40. With chamber door 11 securely attached to chamber 12 so that it hermetically seals the chamber, the pump 38 can partially evacuate the chamber to pressures of 1 millitorr. Sensor 42 is provided to monitor the chamber pressure.

A gas supply unit 44 communicates an admixture of reactive gas to stations 22 and 26 to provide a reactive sputtering process. Similarly, gas supply unit 44 supplies an inert or nonreactive gas to deposition station 24 for generating the gas-discharge plasma that will provide the sputtering environment for that station. In addition, each deposition station 22, 24, 26 is provided with a separate source of electrical power to control the sputtering taking place at each station. Accordingly, there is provided power supplies 48 to supply the corresponding deposition stations with the appropriate high voltage required for the sputtering process. Again for clarity, the conduits and electrical lines which communicate the gases and electrical power to each deposition station are not fully illustrated in the Figures.

Referring now to FIG. 2B, it can be seen that support cylinder 20 includes an outer cylindrical jacket 50 and an inner cylindrical jacket 52. The outer and inner jackets 50 and 52 relatively situated concentric to each other are dimensioned so that a space is formed between the two jackets. Both outer and inner jackets 50 and 52, respectively, are formed from hot rolled steel. Additionally, the outer surface of jacket 50 (and, therefore, support cylinder 20) is provided with a polished, hard chrome coating.

Inlet and outlet coolant lines 54 and 56, respectively, carry a coolant to and from the support cylinder. The lines 54, 56 pass through a rotating coaxial seal 58 of known construction to communicate water (cooled to about 22.degree. C.) to and from the interstitial area between jackets 50 and 52 of support member 20, thereby cooling the support cylinder.

### Demonstration of Making the Super Lattice Quantum Well Films

In an actual demonstration run, high volume quantum well type multi-layer films were fabricated on a large area web coater sputtering machine. Alternating layers of Si_{0.8}Ge_{0.2} and Si were grown on Kapton® and Mylar® substrates from two targets in a magnetron sputtering system with the web coater. (Applicants are confident that the success they had with the silicon and silicon germanium will apply equally well to silicon and silicon carbide layers as described below.) The plasma, web speed, pulse power frequency, pulse duration and power were set to yield a deposition rate of 10 nm/min and 50 alternate Si_{0.8}Ge_{0.2} layers of 10 nm and individual alternating layers of Si each 10 nm to give a total thickness of 1 micron. Prior to deposition, Kapton® and Mylar® substrates were cleaned and a 50 nm thick Si buffer layer was applied to the Kapton® and Mylar® substrates by magnetron sputtering in a web coater. A thin 300 μm thick Si substrate also was used to demonstrate use of a crystalline substrate for web coating. The pulse power supply operated at a frequency of 15 kHz and a pulse width of 2.2 pee for both the Si_{0.8}Ge_{0.2} and Si source targets. The Si_{0.8}Ge_{0.2} source targets power was 3,000 Watts at a belt speed of 3.6 ft/min and the Si source target's power was 3,000 Watts at a belt speed of 2.5 ft/min.

The actual deposition configuration is illustrated schematically in FIG. 2A. A supply roll 14 has Kapton substrate 30 which travels past a bow roller 19 and drum 20 and tensioner 18 and take-up roll 16. The supply roll 14, bow roller 19, drum 20, tensioner 18 and take-up roll 16 rotate in both clockwise and counterclockwise directions to permit substrate 30 to first pass in front of Si_{0.8}Ge_{0.2} target 100 to deposit 10 nm at 10 nm/min of Si_{0.8}Ge_{0.2} and then pass in front of target 6 to deposit 10 nm at 10 nm/min of Si. Double sided deposition of Quantum Well thermoelectric has been made by turning the film over and depositing alternate layers of Si_{0.8}Ge_{0.2} and Si as described above. The supply roll and take-up roll provide axial tension along the length of substrate film and the tensioner provides additional axial tension along the length of the substrate. The bow roller 19 provides tension in both the axial direction and at 90° to the axial direction. Quantum Well thermoelectric films have been formed by DC power sputtering, pulse power sputtering with continuous power to both source targets, and with power to only one source target at a time.

In preferred embodiments the deposition target source 24 is pure Si and deposition target source 26 is Si₈₀Ge₂₀ doped to ˜10¹⁹ phosphorous carriers per cc for n-type film. For P type film, boron was used as the dopant also at ˜10¹⁹ atoms per cc. Antimony could also be used as the N type dopant. The sputtering should be operated using an argon pressure between 0.001 and 0.1 torr. During deposition of films, the substrate should be about five centimeters from the sputtering targets. Preferred processes utilize two 5 kW pulse power magnetrons, one having a source target of Si_{0.8}Ge_{0.2} that is 5 cm×100 cm with a 0.375 cm thickness, and the other having a source target of Si with the same sizes. Substrate 30 on supply roll 14 could be about 1 meter wide×300 meters long. Many other supply roll substrate materials are possible.

Substrates and films can be heated and cooled prior to deposition, during deposition and subsequent to deposition as a means to control structure of individual layers of crystalline films. FIG. 2B shows the central drum with an internal substrate temperature controlled heater. This heater provides substrate temperatures of 325° C. for Kapton and 500° C. for Si substrates. Ion beam assisted deposition may be applied prior to deposition on the substrate and post deposition to anneal the thin films. A laser operating in a range from UV to IR energies may be used to promote crystal growth of thin films. Bow roller 19 and tensioner 18 maintain substrate in tension both perpendicular to length and along length of long substrates.

### High Volume Sputter Machines

As explained above the prior art web coater can produce enough quantum well material per day for about 10 modules of a preferred design. Applicants have developed preliminary designs for high volume sputter machines for greatly increasing production rates of the quantum well film. An important limiting factor in quantum well film production is that the quality of the film decreases substantially if the deposition rate exceeds about 10 nm per minute. The area of the substrate covered by deposition is approximately equal to the effective area of the targets. Therefore, to increase the production rate the target area should be increased. This can be accomplished by increasing the number of targets or increasing the size of the targets. The targets are just like the ones described above for the two-target machine, each one meter long and 5 cm wide other specifications are also the same or similar. With this machine the production rate of quantum well film could be increased by a factor of eight from the two-target machine described above from 1.44 cm³ per day to about 11.5 cm³ per day (enough for 48 modules per machine per day). In another design the substrate film (having a length approximately equal to the circumference of the drum is mounted on a large 4-meter diameter cylindrical drum and targets are spaced entirely around the drum. In the drawing shown, 24 targets are provided which, assuming the same size targets as in the two-target embodiment described above, would provide for a factor or 12 improvement in the film production rate resulting in a daily production rate of about 72 modules per day per sputter machine. Applicants have also proposed a larger machine with forty 5 cm×100 cm targets to provide a factor of 20 improvement in the production rate which would result in a production per machine of 28.8 cm³ per day. This is enough quantum well material for 120 modules of the type 3 preferred design. If we assume a cost of about $2,000 per 24-hour operation of the machine, the estimated cost of the quantum well material would be roughly $70/cm³.

### Preferred Egg-Crate Module Design

A preferred thermoelectric module is an egg-crate type module approximately 5.55 cm×5.55 cm square and 0.7 cm thick. The module consists of a 10×10 matrix of thermoelectric elements with each element being an approximate cube about 5 mm×4.9 mm square and about 3 mm thick. Forty nine of the thermoelectric elements are P type conductors and forty nine are N type conductors and they are connected in such a way that they are electrically in series but thermally in parallel. Two of the corners are used to fasten power leads and so do not contain thermoelectric elements. The electrical connectors are formed by thermally spraying molybdenum and aluminum (or copper) metal as described in Applicants' employer's prior art U.S. Pat. No. 5,875,098 (see FIGS. 19A and 19B in that patent and the related text). The fabrication of the egg-crate itself is also described in the U.S. Pat. No. 5,875,098.

Each thermoelectric element consists of twelve layers of quantum well films with a spacer layer of Kapton film in between each quantum well film stack. The Kapton film serves two purposes; it bonds the layers together and also acts as a thermal insulator to reduce the heat flux. Reducing the heat flux permits the use of fewer elements that are shorter. This means that less quantum well material is required resulting in a significantly lower cost with only a small sacrifice in efficiency due to some bypass heat loss through the Kapton.

The quantum well film for this module and the process for making it is described above. A preferred quantum well film is comprised of a Kapton substrate that is 200 μm thick and 400 alternating layers of silicon and silicon carbide deposited on one surface of the Kapton substrate. The thickness of each layer of silicon is 10 nm and each layer of SiC is also 10 nm. The total thickness of the 800 layers is about 8,000 nm or 8 microns so the quantum well film including its substrate is about 208 microns thick. A step-by-step procedure for making the egg-crate module is described in the section below.

### Preferred Procedure for Fabricating the Egg-Crate Module

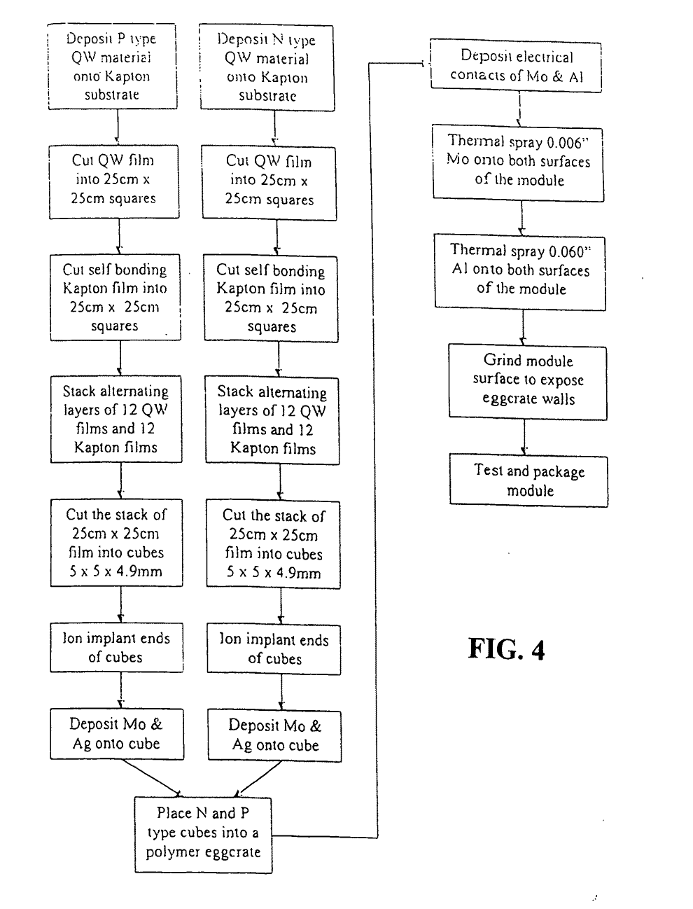

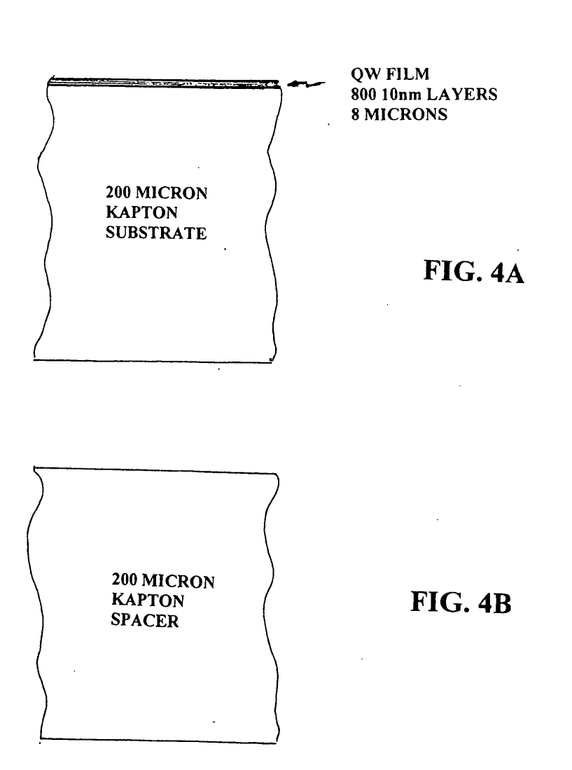

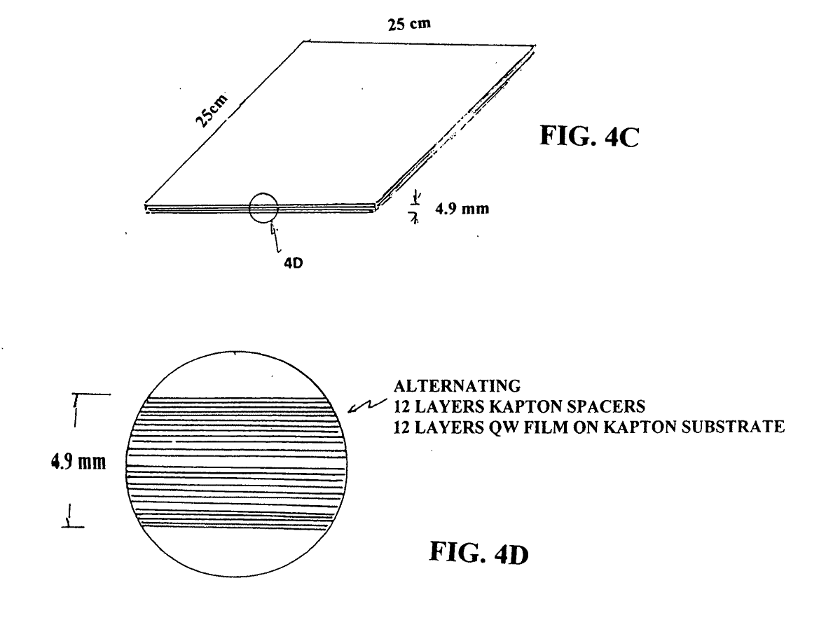

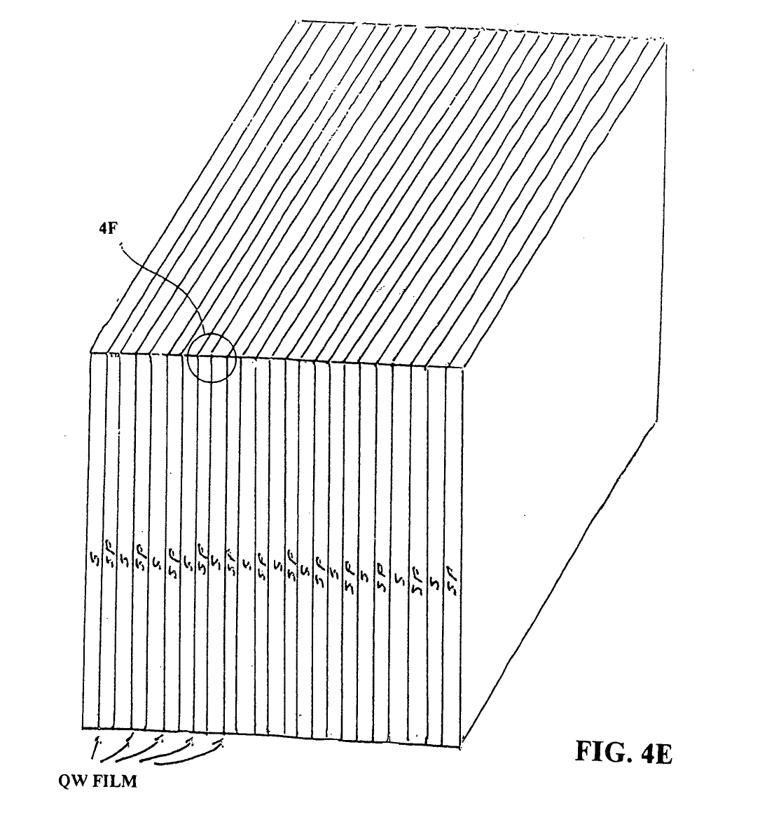

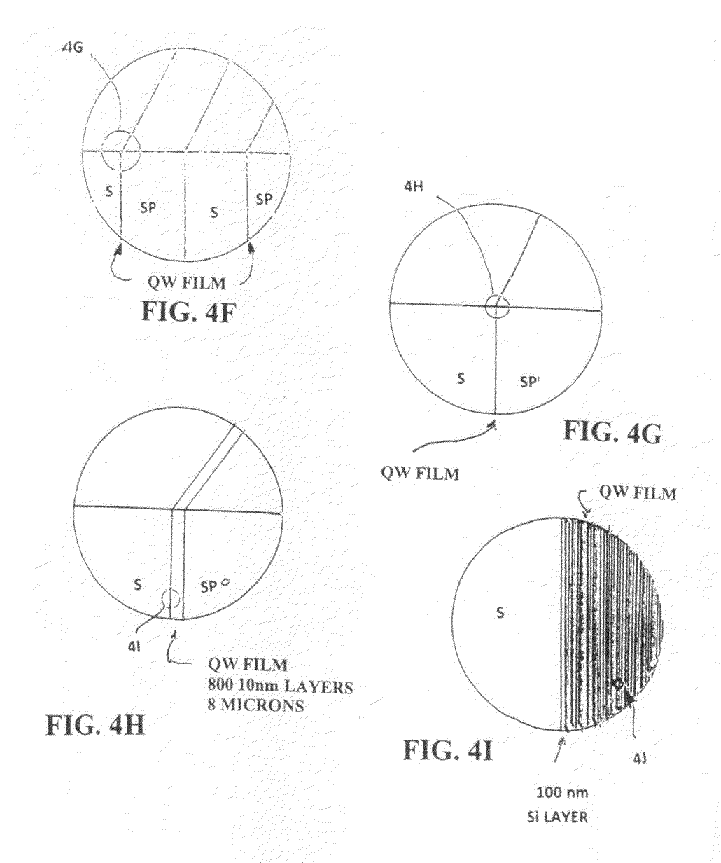

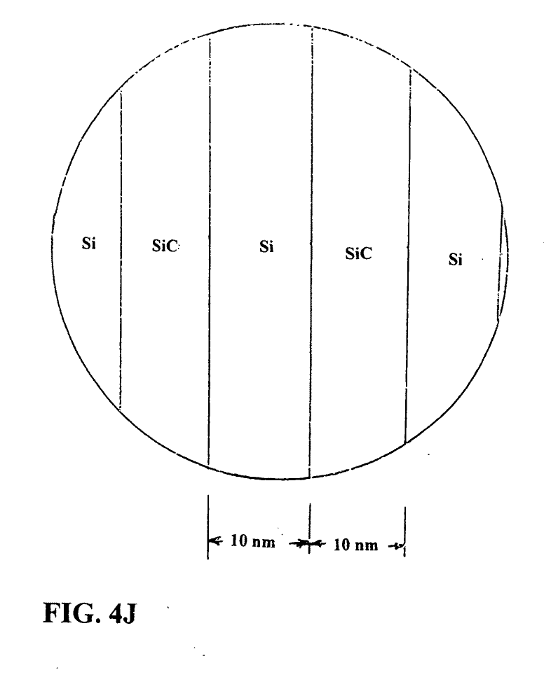

FIG. 4 is a flow chart describing the fabrication process of the preferred embodiment. The fabrication process is also described in the text below with respect to silicon and silicon carbide n-legs and p-legs.
1) Prepare quantum well film as described above. The preferred embodiment uses alternating layers of Si and SiC. The quantum well film for this module and the process for making it is described in general above. For this embodiment, each film layer comprises a Kapton substrate that is 200 μm thick and 400 alternating layers of silicon and silicon germanium deposited on one surface of the Kapton. The thickness of each layer of silicon is 10 nm and each layer of SiC is also 10 nm. The total thickness of the 800 thin film layers is about 8,000 nm or 8 microns so the quantum well film including the substrate is about 208 microns thick. A cross section of a single quantum well film with the 800 quantum well layers (400 quantum well periods) is shown in FIG. 4A. About 0.144 cm³ of the quantum well film (p-type and n-type) is needed for a typical 100 leg thermoelectric module. (The first layer on the Kapton film should be Si and in preferred embodiments this first layer could be significantly thicker than 10 nm, for example a 100 nm first Si layer is recommended.)
2) Cut the quantum well film into 25 cm×25 cm sections and cut an equivalent number of 200 micron thick Kapton film depicted in FIG. 4D into 25 cm×25 cm sections to function as spacer films between the quantum well films.
3) Stack twelve quantum well films and twelve Kapton films alternately on top of each other. The top layer of the stack is a Kapton spacer and the bottom layer is a Kapton substrate. These top and bottom layers of Kapton will help to protect the quantum well layers from damage. The stack of 25 cm×25 cm films is shown in FIG. 4C. A cross section of the stack is shown in FIG. 4D.
4) The Kapton spacers are self-bonding films that can be bonded by heating at 350° C. for one hour while holding the stack under compression. Once the stack of twelve QW films and twelve Kapton spacers are fully bonded the resultant stack up will be about 4.9 mm thick.
5) Cut the stack of QW films into blocks that are 3 mm×5 mm square. This will result in cubes that are 3 mm×5 mm×4.9 mm. An excimer laser has been shown to be effective at cutting quantum well films.
6) Fasten the p-type legs into a fixture and ion implant one of the 4.9 mm×5 mm surfaces of the legs with boron ions. The boron ions are implanted to a depth of 112 nm and then to a depth of 77 nm and then finally 40 nm. Implanting boron ions into the surface of the leg dopes the semi conducting materials making them more electrically conductive to provide a low contact resistance when the leg is bonded to a metal conductor as described below. (Aluminum can be substituted for boron. The depths could be increased proportionately with the deepest of about 500 nm. Depositing at three different depths help provide for continuity of ion concentration.)
7) Step 6 is repeated on the surfaces of the legs that are opposite the surface that was implanted in step 6.
8) Steps 6 and 7 are repeated for the n-type legs except phosphorous ions are implanted to depths of 43 nm, 30 nm and 17 nm. (Nitrogen or antimony can be substituted for phosphorous. Other implantation depths may be preferred.)
9) The surfaces that were ion implanted are sputter coated with a 5 μm thick layer of molybdenum, or MoSi₂, and then a 5 μm thick layer of silver. The silver is a soft compliant material and can yield to reduce strain due to thermal cycling and then anneal at a temperature of 300° C.
10) The coated surfaces of the legs are then annealed at 900° C. for ten seconds. The surface must be rapidly annealed (such as by laser, microwave, or flash lamp) to prevent damage to the Kapton spacers and substrates in the bulk of the leg. Annealing the leg ends allows the implanted dopant to diffuse into a stable location in the leg matrix where it can function properly plus the high temperature allows the molybdenum, or MoSi₂, to react briefly with the silicon to form a thin layer of MoSi₂. Since MoSi₂ has a band gap closer to that of the silicon it forms a low-energy barrier resulting in a lower contact resistance.
11) Fabricate a liquid crystal polymer eggcrate as described in U.S. Pat. No. 5,875,098. This eggcrate is designed to hold 49 P type legs and 49 N type legs in a 10×10 matrix. Two corner positions that would normally hold a leg are used to attach electrical contacts leaving 98 positions that can hold thermoelectric legs.
12) Load the n-legs and p-legs into the egg-crate and connect them electrically in series using the metal thermal spray technique described in the U.S. Pat. No. 5,875,098 in the section entitled “PROVIDING ELECTRICAL CONNECTIONS FOR THERMOELECTRIC ELEMENTS” and FIGS. 19A and 19B of that patent. Complete the fabrication of the module as described in the '098 patent.

When thermoelectric modules are fabricated in high volumes, following the twelve steps previous described, the fabrication costs of these modules should be about $30 per module. When operated at a hot side temperature of 350° C. and a cold side temperature of 50° C., this module will produce more than 46.8 watts of electrical power for a cost per watt of less than $0.65. The efficiency of the module is expected to be about 21.4 percent.

### Preparing N-Legs and P-Legs of Si/SiC

N-type SiC is readily available for industrial integrated circuit applications and was utilized in the fabrication of the modules described in the Applicants' prior art patent covering the modules with n-type Si/SiC legs. For those prior art demonstrations the n-type SiC and silicon are alternately bombarded with argon ions to alternately deposit n-type SiC and silicon. However, p-type SiC material for sputtering targets are not to the best of Applicants' knowledge in early 2010 sold commercially. For those prior art demonstrations the p-legs were prepared using B4C and B9C for the super-lattice legs. Applicants could have used p-type SiGe for the p-legs.

Since high purity p-type SiC targets have not been commercially available, Applicants decided to try to use n-type SiC and p-doped silicon to produce p-type SiC quantum well legs. To have a chance at success, Applicants used heavily p-doped (to 10²¹ atoms /cc) silicon targets. The net effect is that the large amount of p-type dopant (boron in this case) in the silicon layer resulted in a p-type silicon and silicon carbide quantum well leg with excellent thermoelectric properties. Sputtering rates of 4 minutes, 27 seconds for each 10 nanometer layer were used for n-type SiC and 1 minute for each 10 nanometer for p-type silicon. Thicknesses of 4 nm for the silicon and 10 nm for the SiC were deposited. The deposition temperature was about 625° C. A total of 50 layers of Si and 50 layers of SiC are typically deposited on a silicon single crystal substrate.

The thermoelectric qualities (Seebeck coefficient and electrical resistivity) of the silicon carbide—p-doped silicon samples were measured and the results of the measurements are compared to the Seebeck coefficient and electrical resistivity of commercially available bulk p-type bismuth telluride material which is currently considered the best commercially available p-type thermoelectric material. The Seebeck coefficient for the new p-type silicon carbide super-lattice layer was 985 microvolts per ° C. as compared to 180 microvolts per ° C. for the bismuth telluride sample. This Seebeck coefficient of 985 microvolts per ° C. is about the same as the Seebeck coefficients that Applicants have measured for p-type silicon germanium quantum well super-lattice samples which are in the range of about 1,000 microvolts per ° C.

### Other Techniques for Making Quantum Well Si/SiC N-Legs and P-Legs

### Hot Pressed P-Type Sputter Targets

As indicated above n-type silicon carbide sputter targets are available from many sources. However, p-type sputter targets are not generally available. Applicants propose to fabricate their own p-type SiC sputter targets. Silicon carbide powders are mixed with about one percent aluminum and are hot pressed at temperatures of about 1500 to 1700° C. then oven heated to 2300° C. to evenly distribute and activate the aluminum to form p-type silicon carbide sputtering targets which are then used with silicon sputtering targets doped to about 10¹⁶ to produce the super-lattice quantum well layers. Boron can be substituted for the aluminum.

### RF Reactive Sputtering

Another proposed technique utilizes radio frequency reactive sputtering. In this case the sputtering target is silicon. To produce the silicon carbide layers a gas mixture of argon and methane (CH₄) is used to produce the SiC layers. The composition of the films can be controlled by varying the relative pressures of the argon and the methane. To produce the silicon layers, the methane flow is stopped so the gas flow is only argon. The sputtering chamber is maintained at a pressure of 3×10⁻⁷ ton. RF power is controlled within 100 to 200 watts. The n and p features of the nano-structured Si/SiC materials can be controlled by the choice of dopants for the silicon targets.

### Co-Sputtering

Silicon carbide films can also be produced by co-sputtering the carbon and the silicon from separate targets at the same time. The n and p dopants are preferably added to the silicon targets. Silicon layers can be applied using the same target used for the co-sputtering of the silicon carbide or if a different dopant concentration is required a separate silicon target must be used. Co-sputtering equipment is available from 4 Wave, Inc.

### Abundance of Silicon and Carbon

There exist a wide variety of semiconductor materials that are potentially available to fabrication of quantum well thermoelectric modules. However many of these materials are rare and as a result become expensive when demand is high. Applicants preferred quantum well material for their preferred quantum modules is silicon and carbon, two of the most abundant materials on earth. The price of high purity silicon and silicon carbide can fluctuate with economic conditions but there will never be a shortage of the raw materials. Factories to refine the materials can be built to meet any demand. Therefore, with the utilization of these materials, costs, at least over a period of years, should continue to go down as demand goes up.

### Boron Carbide N-Legs and P-Legs

In U.S. Pat. No. 6,828,579 referred to above the p-legs were comprised of alternating layers of B4C and B9C and the n-legs were comprised of silicon carbide and silicon. As explained above Applicants have determined that there are important advantages in having both types of legs comprised of the same basic materials. Therefore Applicants have disclosed in this specification techniques for making modules with poly-types of boron carbide in both the n-legs and the p-legs.

### Boron Carbide N-Legs

As indicated in the Background section for many years, poly-types of boron carbide have been known as a good p-type semiconductor material. Attempts to create n-type boron carbide included attempts to dope the boron carbide with nickel, but at about 50° C. the material reverted to p-type. More recently however researchers in various semi-conductor fields have developed methods of making n-type boron carbide materials. For example a few references are listed below:
1) In U.S. Pat. No. 6,774,013 n-type boron carbide is prepared by decomposition of closo-17-dicarbaddodecarbonate (C2B10H12). This patent is incorporated herein by reference.
2) Yoshiaki Aoki, et al, 2000 American Institute of Aeronautics and Astronautics, Evaluation of Thermoelectric properties of Sintered B₄C—B₁₃P2 Ceramics. In this reference 90 percent B₄C and 10 percent B₁₃P₂ powders were pressed to 30 MPa and heated to 2,000 K in a vacuum of about 10 Pa to product the n-type boron carbide.

Applicants expect to utilize these n-type materials as sputtering targets to prepare super-lattice quantum well boron carbide n-legs.

For example a proposed boron carbide thermoelectric module would include p-legs comprised of alternating super-lattice layers of B4C and B9C and n-legs comprised of alternating super-lattice layers, at least one of the alternating layers being comprised of an n-doped polytype of boron carbide and the other layer being a different semiconductor. Alternatively, super-lattice layers of p-type boron carbide could be combined with super-lattice layers of an n-doped polytype of boron carbide or the other super-lattice layers could be n-doped silicon. The use of n-doped silicon layers to produce an n-type leg is an extrapolation of Applicants' success in producing a p-type leg with p-doped silicon super-lattice layers in combination with super-lattice layers of n-type silicon carbide.

### Fabrication Cost Per Module

The major cost of the thermoelectric module described above is expected to be the cost of the quantum well material. The volume of quantum well material in the preferred type 3 egg-crate module is 0.144 cm³/module. (The quantum well thickness is 0.0008 cm. The film area per film in each leg is 0.5 cm×0.3 cm or 0.15 cm². So the volume of quantum well material per film in each leg is 0.0001 cm³. The number of films per leg in the preferred embodiment is 12 so the volume of quantum well material per leg is about 0.0014 cm³. There are approximately 100 legs per module so the volume of quantum well material per module is about 0.144 cm³.)

With an estimate of $70/cm³ for the cost of the quantum well material, the quantum well material in the preferred embodiment would be about $10.00. This $10.00 is similar to the cost of the material used in the 14 watt bismuth telluride module currently being marketed by the Applicants' employer but the quantum well module will generate more than 40 watts of power. If we use $10/cm³ for the cost of the quantum well material, the quantum well material in the preferred embodiment would be about $1.50. So the advantages of the present invention compared to current commercial thermoelectric modules is better by factors of somewhere between about 3 and 18 depending primarily on the production costs.

### Thermoelectric Module Design

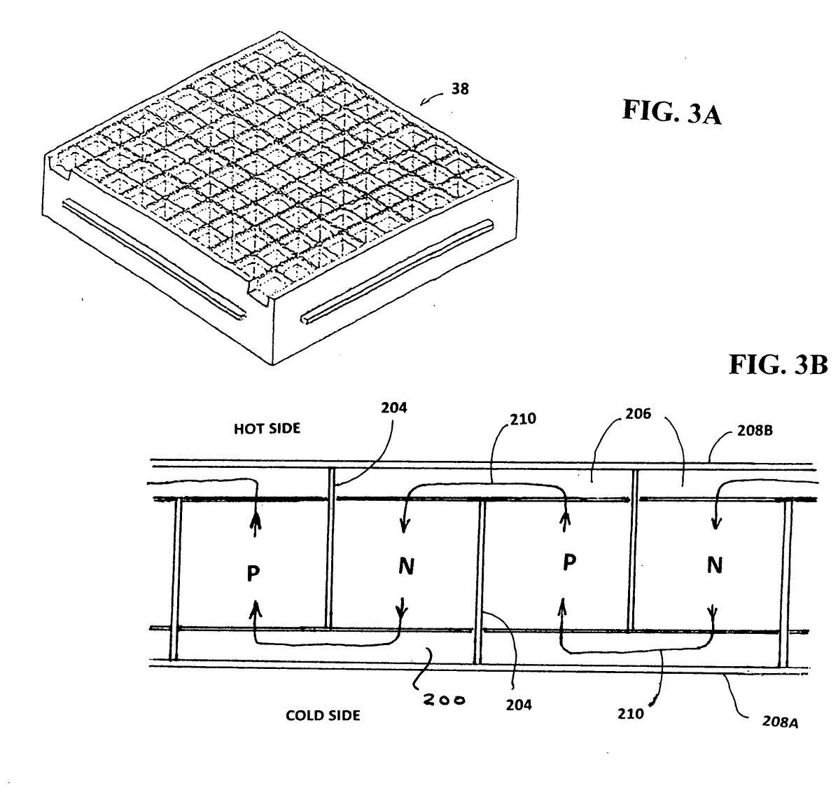

In a first preferred embodiment, 400 quantum well silicon and silicon carbide super-lattice layers are grown on a 200 micron thick substrate in a web coating sputtering machine. The preferred substrate is Kapton coated with a 100 nm buffer layer of silicon. On the silicon buffer layer are deposited alternating 10 nm layers of silicon carbide and silicon. The thickness of the quantum well material on the 200 micron thick substrate is about 8 microns, so the quantum well film is about 208 microns. The 8 micron film on the 200 micron substrate and a 200 micron spacer are assembled in sets with thicknesses of about 408 microns and the sets are stacked 12 high (12×408 microns) to produce sheets of thermoelectric material about 0.49 cm thick. The stack of quantum well film and spacers is cut into legs with dimensions of about 0.3 cm×0.5 cm×0.49 cm. The legs are treated at both hot and cold ends with an ion implantation procedure and sputter coated at both hot and cold ends with molybdenum and silver to improve electrical connections between the legs. The legs are then assembled into a thermoelectric egg-crate, similar to prior art thermoelectric egg-crates as shown in FIGS. 3A and 3B. At the bottom of each leg is a complaint cold member 200 comprised of a flexible material such as copper felt. Above complaint cold member 200 is a thin layer of an electrical insulator 202 such as Al2O3. Above the insulator layer is a thin electrical conductor 203 (preferably copper film that connects n-legs to the p-legs except where the egg-crate spacers 204 separate the legs at the cold side. Each of the e-legs and the p-legs preferably have been treated as described at the bottom and top with ion implantation and sputter coated with molybdenum and/or silver to assure good electrical contact between the copper film and the quantum well layers. Arrows 210 show the path of electron flow through the thermoelectric legs. Electrons flow from hot to cold through the n-legs and from cod to hot through the p-legs. Electric current is normally assumed to flow in the opposite direction. Most references refer to electrons flowing from hot to cold through n-legs and holes flowing from hot to cold through p-legs. Both sides of the legs have also been treated with ion implantation and sputter coated with molybdenum and/or silver as described above. The electrical connection between the n-legs and the p-legs at the hot side of the module is provided with iron shoes 206. The use of the iron shoes is preferred in order to avoid any cross contamination of the n-legs and the p-legs. Above the iron shoes is a thin layer of copper film (not shown) which is added to improve conduction within the module. At both the cold side and the hot side a thin electrical insulator layer 208A and 208B is provided to avoid any undesired shorting among the legs.

The ratio of insulating material to quantum well material in the legs is about 50. The estimated maximum efficiency of the module is about 21.4 percent. This preferred embodiment is a thermoelectric 10×10 egg-crate type module about 5.55 cm×5.55 cm×0.7 cm. The module has 98 active thermoelectric legs, each leg having more than 4,800 super-lattice quantum well layers. Applicants expect to be able to produce more than two hundred of these modules per day per web coating machine.

With an estimate of $70/cm³ for the cost of the quantum well material, the quantum well material in the preferred embodiment would be about $10.00. This $10.00 is similar to the cost of the material used in the 14-watt bismuth telluride module currently being marketed by Applicant's employer but the quantum well module will generate more than 40 watts of power. If we use $10/cm³ for the cost of the quantum well material the quantum well material in the preferred embodiment would be about $1.50. So the advantage of the present invention compared to current commercial thermoelectric modules is better by factors of somewhere between about 3 and 18 depending primarily on the production costs. Applicants expect to manufacture the modules for about $40 per module at a cost per watt of about $0.85/watt.

### Other Egg-Crate Designs

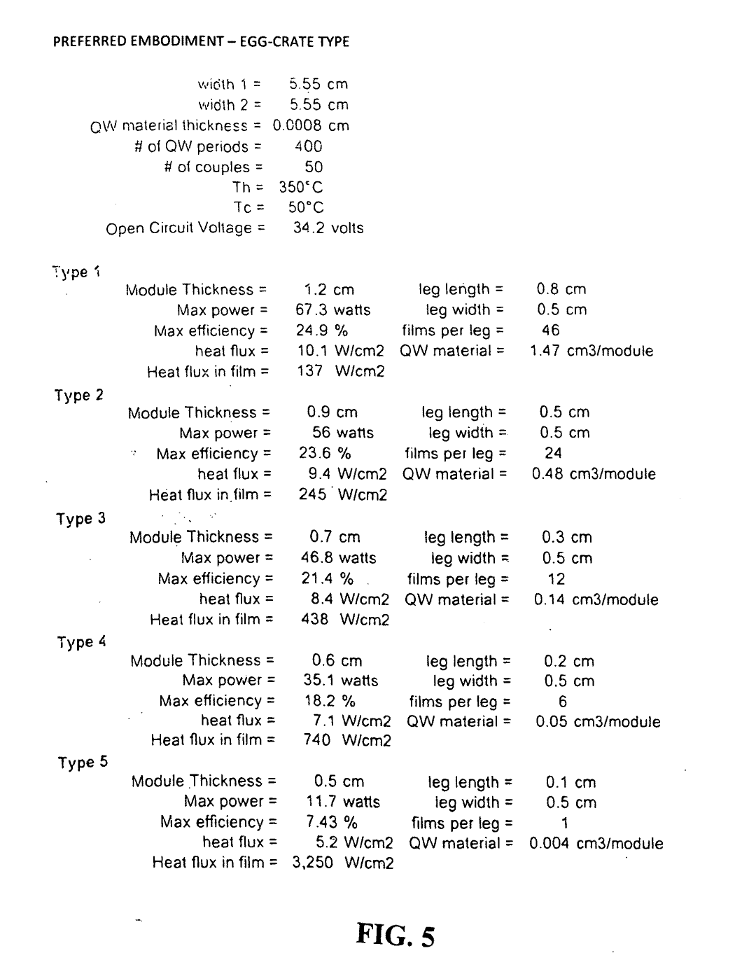

The reader will note that according to the above description, the amount of quantum well material in each module is very small compared to the substrate and spacer material. There are many advantages associated with the relatively small volume of quantum well material compared to the spacer and substrate material. The main advantage is cost. The quantum well material cost is many orders of magnitude greater than the substrate and spacer material when figured on a volume basis. A second advantage is the thermal conductivity of the substrate and spacer material is orders of magnitude lower on a volume basis than that of the quantum well material. This has the effect of reducing greatly the thermal flux through the thermoelectric module. The down-side of reducing the relative amount of quantum well material in the thermoelectric legs is that ideally most of the thermal energy must pass through the quantum well layers. When the area of the quantum well layer is too small compared to the area of the leg, then the heat flux becomes too high and the desired temperature difference can not be achieved. This means that there is a practical lower limit on the amount of quantum well material needed in a module that will depend in large part on the specific application. Use of the spacers and the inclusion of the insulating substrates in the design of the modules as indicated in FIG. 5 also reduce somewhat the power output and the module efficiency.

Applicants have performed calculations to estimate the effects of varying the quantity of quantum well material in the egg-crate described above. The results are shown in FIG. 5. In FIG. 5 five types (Types 1 through 5) of egg-crate design specifications are shown each with a different number of quantum well films per leg. In each case the films or film was the film described in the preferred egg-crate embodiment described above, namely an 8 micron quantum well layer of 400 periods of silicon and silicon-germanium layers on a 200 micron Kapton substrate. The preferred embodiment is Type 3 with 12 films. Type 1 has 46 of the quantum well film, Type 2 has 24 quantum well films, Type 4 has 6 quantum well films and Type 5 has only one quantum well film. Estimated maximum efficiency varied from 24.9 percent for the module with 46 films to 7.43 percent for the module with only one film. The efficiency of the preferred embodiment is estimated at 21.4 percent. As shown above the fabrication cost of the modules of the preferred embodiments is expected to be roughly proportional to the quantity of quantum well material used in the modules. With this assumption increasing the module maximum efficiency for 21.4 percent to 24.9 percent is expected to increase the module cost by about 300 to 400 percent. Reducing the quantity of quantum well material below 12 films per leg would reduce the cost but the efficiency drops off as a result and with only a few films per leg the module costs other than the film will reduce the potential cost savings.

### Performance Calculations

The calculations showing how the performance of the preferred embodiment was calculated and the assumptions that went into the calculations are shown below.

Material Properties

| | |
|---|---|
| Thermal Conductivity (k) | |
| QW material = | 0.11 W/(cmK) |
| Kapton = | 0.0014 W/(cmK) |
| Eggcrate material = | 0.001 W/(cmK) |
| Seebeck Coefficient (α) | |
| N leg = | −1.14 mV/K |
| P leg = | 0 1.14 mV/K |
| Resistivity (ρ) | |
| N leg = | 1 mΩcm |
| P leg = | 1 mΩcm |

QW film
Substrate is 200 μm thick Kapton
QW film is 8 μm thick
Total film (with substrate) thickness = 200 μm + 8 μm = 208 μm
Spacer between QW films (also acts as an adhesive layer)
200 μm thick Kapton
Leg
Leg size = 3 mm × 5 mm × 4.9 mm
Leg in 4.9 mm dimension consists of:
12 layers of QW film
12 layers of spacer material
12(0.208 + 0.200) = 4.9 mm thick
Volume of quantum well material in one leg
12(0.0008 cm × 0.3 cm × 0.5 cm) = 0.00144 cm³
Module
Legs in one module = 10 × 10 = 100
Volume of quantum well material in one module
100 × 0.00144 = 0.144 cm³
area of module = 5.55 cm × 5.55 cm = 30.8 cm²
Operating Conditions
Hot side temperature = 623° K
Cold side temperature = 323° K
ΔT = 300° K
Tavg = 473° K

Voltage Calculations

| | |
|---|---|
| Leg | V = αΔT = 1.14 × 300 = 342 mV |
| Module | V = 100(0.342) = 34.2 volts (open circuit) |

Resistance Calculations

| | |
|---|---|
| Film | area = 0.0008 cm × 0.5 cm = 0.0004 cm² |
| | length = 0.3 cm |
| | R = ρl/A = 1 × 0.3/0.0004 = 750 Ω |
| Leg | 1/Rₜ = 1/R₁ + 1/R₂ + . . . + |
| | 1/R₁₂ = 12 (1/750) = 0.016 mΩ⁻¹ |
| | Rₜ = 1/0.16 = 62.5 mΩ |
| Module | R = 100 × 0.0625 = 6.25 Ω |

Thermal Calculations

| | |
|---|---|
| Lattice | |
| Thermal Conduction | |
| Film | Q = kAΔT/l = 0.11 × 0.0004 × 300/0.3 = 0.044 |
| | Watts |
| Substrate | A = 0.02 × 0.5 = 0.01 cm² |
| | Q = 0.0014 × 0.01 × 300/0.3 = 0.014 Watts |
| Spacer | A = 0.02 × 0.5 = 0.01 cm² |
| | Q = 0.0014 × 0.01 × 300/0.3 = 0.014 Watts |
| Leg | Q = 12(Qleg + Qsubstrate + |
| | Qspacer) = 12(0.044 + 0.014 + 0.014) = 0.864 |
| | Watts |
| Module | Q = 100 × 0.864 = 86.4 watts |
| Seebeck Heat | |
| Leg | I = V/(2R) = 34.2/(2 × 6.25) = 2.74 amps |
| | Q = αTₕI = 0.00114 × 623 × 2.74 = 1.95 watts |
| Module | Q = 100 × 1.95 = 195 watts |
| Joule | |
| Module | Q = VI/4 = 34.2 × 2.74/4 = 23.4 watts |
| Eggcrate | A = 0.053 cm² |
| | L = 0.7 cm |
| | Q = 0.01 × 0.053 × 300/0.7 = 0.23 watts |
| Total Q | Q = Q_{lattice} + Q_{Seebeck} − Q_{Joule} + |
| through module | Q_{Eggcrate} = 86.4 + 195 − 23.4 + 0.23 = 258 watts |

Module Properties

V = 34.2 volts (open circuit)
V = 17.1 volts (at matched load)
I = 2.74 amps (at matched load)
Ri = 6.25 Ω
P = V × I = 46.8 watts
Q = 258 watts
Efficiency = P/Q (maximum efficiency happens at
39.3 watts) = 39.3/183 = 21.4%
Heat flux = 258/30.8 = 8.4 W/cm²
Heat flux in film = 258/100/12/(.0008 × 0.5) = 538 W/cm²

In summary the Seebeck coefficient of these films has been measured repeatedly by Applicants and is in the range of about 1000 microvolts/° C. The open circuit voltage per leg is the product of the Seebeck coefficient and the temperature difference (assumed to be 300 C). The film resistance is estimated to be 0.750 ohms. The film resistance per leg is 1/12 of that at 0.0625 ohms and the module resistance is 100 times that or 6.25 ohms. The heat flow through the module is estimated based on known thermal conductivity of the module materials and the result for the preferred egg-crate module is 258 watts. Estimated current at maximum power is estimated by assuming that the operating voltage will be ½ the open circuit voltage and that all of the current will flow through the quantum well film. The operating current is then obtained by dividing the operating voltage by the module “film” resistance and the electric power produced by the module is estimated to be the product of the operating current and the operating voltage or 46.8 watts. The total power flowing through the module in watts is the sum of the electric power plus the heat flow in watts through all of the components of the module which is estimated to be 258 watts. The efficiency of the module is the electric power divided by the total power flowing through the module which is estimated to be 21.4 percent.

### Substrates for Quantum Well Thermoelectric Material

As described in U.S. patent '467, '387, '964 and '965, quantum well thermoelectric material is preferably deposited in layers on substrates. For a typical substrate as described in those patents, heat loss through the substrate can greatly reduce the efficiency of a thermoelectric device made from the material. If the substrate is removed some of the thermoelectric layers could be damaged and even if not damaged the process of removal of the substrate could significantly increase the cost of fabrication of the devices. The present invention provides a substrate that can be retained. The substrate preferably should have a low thermal and electrical conductivity with good thermal stability and strong and flexible.

### Kapton®

Kapton is a product of DuPont Corporation. According to DuPont bulletins:

Kapton® polyimide film possesses a unique combination of properties that make it ideal for a variety of applications in many different industries. The ability of Kapton® to maintained its excellent physical, electrical, and mechanical properties over a wide temperature range has opened new design and application areas to plastic films.

Kapton® is synthesized by polymerizing an aromatic dianhydride and an aromatic diamine. It has excellent chemical resistance; there are no known organic solvents for the film. Kapton® does not melt or burn as it has the highest UL-94 flammability rating: V-0. The outstanding properties of Kapton® permit it to be used at both high and low temperature extremes where other organic polymeric materials would not be functional.

Adhesives are available for bonding Kapton® to itself and to metals, various paper types, and other films.

Kapton® polyimide film can be used in a variety of electrical and electronic insulation applications: wire and cable tapes, formed coil insulation, substrates for flexible printed circuits, motor slot liners, magnet wired insulation, transformer and capacitor insulation, magnetic and pressure-sensitive tapes, and tubing. Many of these applications are based on the excellent balance of electrical, thermal, mechanical, physical, and chemical properties of Kapton® over a wide range of temperatures. It is this combination of useful properties at temperature extremes that makes Kapton® a unique industrial material.

### Kapton® Substrate

Applicants have demonstrated that Kapton can be useful as a substrate film for super-lattice thermoelectric layers when high temperature (i.e. greater than 350 C) use is not planned. Applicants have shown that an amorphous silicon layer laid down with short crystalline range orders between the Kapton® substrate and the series of very thin conducting and barrier layers greatly improve thermoelectric performance especially for n-type layers. The preferred technique is to lay it on about 100 nm thick in an amorphous form then to at least partially crystallize it by one or more of a variety of techniques such as thermal or laser or metal-induced or explosion or microwave induced re-crystallization techniques or combinations of these techniques. When Kapton® is used as a substrate it can be mounted on a crystalline base that can be sand blasted off of the Kapton® after the thermoelectric film is deposited.

### Silicon

Silicon is a potential substrate material, but its thermal conductivity is much greater than Kapton. Si has also been used by Applicants as a substrate for depositing Si/SiGe alloys. Si was available commercially in films as thin as 5 microns from suppliers such as Virginia Semiconductor with offices in Fredricksburg, Va. The silicon film is stable at much higher temperatures than Kapton. Silicon film may be attractive in some applications especially very high temperature applications especially if it can be obtained in extremely thin sheets. Also Applicants have experimented with porous silicon which has very low thermal conductivity properties as compared to silicon. If the pores beginning on one side of the film can be controlled to within a micron or less from the other surface, the porous silicon film could make a very good substrate material. Alternatively the entire substrate could be removed by etching the Silicon to the point where the quantum well layers begin. In this case it may be necessary to bond the quantum well films to Kapton or glass with a low thermal conductivity to provide structural support to the films.

### Other Substrates

Many other organic materials such as Mylar, polyethylene, NaCl and polyamide, polyamide-imides and polyimide compounds could be used as substrates. Other potential substrate materials are a variety of silicon on glass or silicon on insulator materials as well as oxide films such as SiO₂, Al₂O₃ and TiO₂. Mica could also be used for a substrate. As stated above, the substrate preferably should be very thin and a very good thermal and electrical insulator with good thermal stability, strong and flexible. At very high temperatures substrates glass or ceramics with low electric and thermal conductivity could be used. A Si₃N₄ layer can be employed between the substrate and the SiC layer to improve the quality of the SiC layers.

### Double Side Coating of Kapton Film

It is possible to deposit the n and p materials at the same times on opposite sides of the substrate. One technique is to coat one side of the Kapton as explained above then remove the film and coat the other side. Another technique is to arrange the film on a web coater as a continuous Mobius strip so that both sides can be coated at the same time without removing the film.

The advantage of this process is to balance out the stresses that are developed as the films are deposited and also the stresses the form by the differences between the thermal expansion of the SiGe alloys and the high thermal expansion of Kapton or the low thermal expansion of Si. Also, the cost of the sputtering operation is reduced. Samples can also be prepared with the coatings separately deposited. Such samples were able to endure excellent adhesion when rolled up in the reverse direction so the second deposition could be performed.

### Need for Crystalline Quantum Well Legs

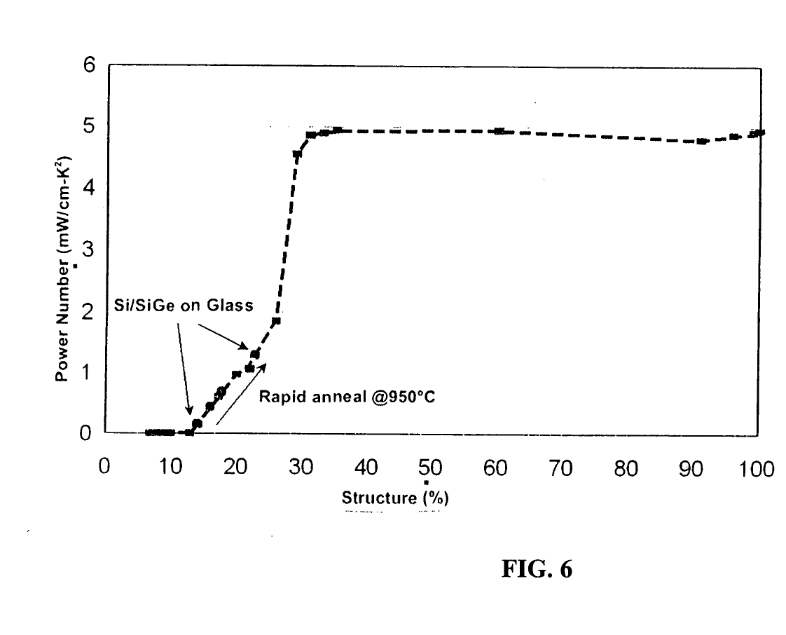

Applicants' tests and theoretical studies have shown that there is a strong correlation between the crystallinity of the quantum well legs and the thermoelectric properties. Their studies show that if the semiconductor material in the legs is amorphous there is no significant improvement in the thermoelectric properties. If the legs are near perfect crystals the thermoelectric properties are greatly enhanced. There tests and studies however further suggests that the substantial improvement in performance is between amorphous and about 25 percent crystalline. (FIG. 6 shows the results of experiments using Auger and TEM analysis showing how the percent of crystallinity in the thin quantum well film affects the thermoelectric properties of the super-lattice layers.) Then there is little or no improvement in electrical properties between about 30 percent crystalline and 100 percent crystalline. The net conclusion of these studies is that it is important that procedures for the production of the quantum well materials be designed to produce at least 30 percent crystalline semiconductor thermoelectric material and that perfect crystallinity in not necessary.

### Egg-Crate Designs with More or Less QW Material

Persons skilled in the thermoelectric art will recognize that many other egg-crate designs are possible that will provide the advantages of the thermoelectric egg-crate which include the electrical isolation of the legs except where they need to be connected and to permit the electrical connections to be simply sprayed onto the hot and cold surfaces of the module. Many sizes are possible. The number of legs could be tailored as desired. Series and parallel connections can be easily designed into the modules.

The egg-crate describe in the U.S. Pat. No. 5,875,098 is molded utilizing a thermoplastic material that is satisfactory for operation at temperatures up to about 35° C. For modules designed for higher temperature operation will require a higher temperature egg-crate. Such a higher temperature egg-crate is described in detail in Applicants' U.S. patent application Ser. No. 12/590,653 filed Nov. 12, 2009, which is incorporated herein by reference.

### Egg-Crate with Wide Thin Legs

A preferred embodiment easily adapted for use with these quantum well film is a one-dimensional egg-crate as compared to the two-dimensional 10×10 egg-crate described above and shown in FIG. 3A. In a preferred one-dimensional egg-crate embodiment the quantum well film and spacer stack as shown in FIG. 4C is only 0.816 mm high (i.e. only two layers of the 208 micron quantum well film and two layers of spacers for a total thickness of 0.816 mm). The stack is sliced and diced into 100 quantum well legs which have dimensions of 0.816 mm×5 cm×3 cm. An egg-crate is provided with leg spaces a little larger than the quantum well legs. The walls of the egg-crate are designed so that when electrical contacts are sprayed on as described in U.S. Pat. No. 8,856,201, all of the legs will be electrically isolated from each other except where they are connected in series at the hot and cold sides on the module.

### Other Quantum Well Super-Lattice Material Combinations

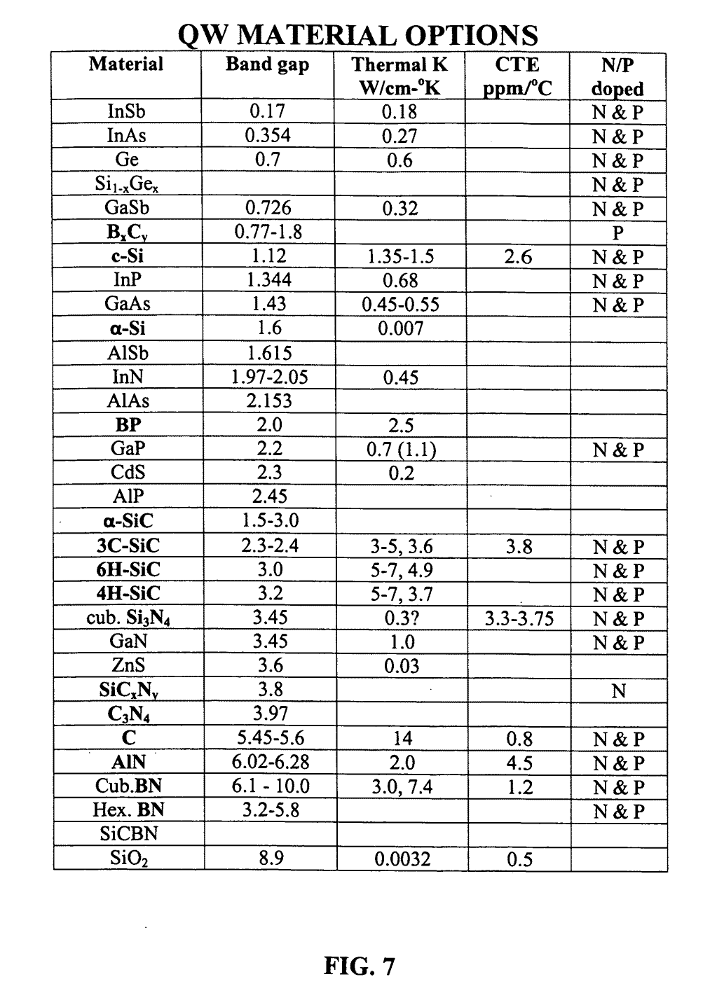

Applicants' experiments have shown that the ability to produce super-lattices with combinations of semiconductor materials along with appropriate doping provides a means for creation of a large variety of new materials with quantum well properties. Applicants' techniques basically include choosing materials or combinations of materials that constitute semiconductor materials with significant band gaps. Materials with differing band gaps are appropriately doped to produce n-properties and formed into thin super-lattices to produce n-legs. And materials with differing band gaps are appropriately doped to produce n-properties and formed into thin super-lattices to produce n-legs. Preferably the materials chosen for the p-legs are similar to the materials chosen for the n-legs. This helps to minimize problems associated with differing thermal expansion during operation. FIG. 7 provides a list of candidate semiconductor materials suitable for development into quantum well super-lattice materials and FIG. 8 provides a list showing some candidate combinations for super-lattice legs, with well material and barrier materials identified. Appropriate doping can be added to turn the super-lattice combinations into n-legs or p-legs. Normally Applicants would expect that the appropriate doping would be an n-dopant added to the “well” layers for an n-leg and a p-dopant added to the “well” layers for a p-leg; however, as demonstrated for the silicon-silicon carbide p-leg described above and actually fabricated and tested by Applicants, light n-doping to the silicon carbide well layer and heavy p-doping to the silicon barrier layer produced an excellent p-type quantum well leg.

While the above description contains many specificities, the reader should not construe these as limitations on the scope of the invention, but merely as exemplifications of preferred embodiments thereof. Those skilled in the art will envision many other possible variations within its scope. The preferred layer thickness is about 10 nm; however, layer thickness could be somewhat larger or smaller such as within the range of 20 nm down to about 5 nm. It is not necessary that the layers be grown on film. For example, they could be grown on thicker substrates that are later removed. There are many other ways to make the connections between the legs other than the methods discussed. Efficiency values referred to in this specification could were generally based on a delta T of about 200° C. Substantially higher efficiencies could be realized at higher delta T's. Accordingly, the reader is requested to determine the scope of the invention by the appended claims and their legal equivalents, and not by the examples which have been given.

We claim:

1. A low cost quantum well thermoelectric module comprising:
A) a plurality of super-lattice quantum well n-legs, each n-leg in said plurality of n-legs comprising:
1) a plurality of n-type quantum well films, each quantum well film in said plurality of n-type quantum well film being comprised of a plurality of super-lattice alternating layers one of each of said alternating layers being comprised primarily of a material adapted for n-type conduction and the other of each of said alternating layers being comprised primarily of a material adapted to provide an insulating barrier layer, each layer having a thickness of less than 20 nm,
2) a plurality of films comprised of electrical and thermal insulating material separating at least a portion of said quantum well films in said plurality of quantum well films from other quantum well films in said plurality of quantum well films,
wherein the quantum well film in each of the plurality of n-legs define a volume of quantum well film and the plurality of films of insulating material in each of the plurality of n-legs define a volume of insulating material and the ratio of the volume of insulating material to the volume of quantum well material is at least 12.
B) a plurality of super-lattice quantum well p-legs, each p-leg in said plurality of p-legs comprising:
1) a plurality of p-type quantum well films, each quantum well film in said plurality of p-type quantum well film being comprised of a plurality of super-lattice alternating layers one of each of said alternating layers being comprised primarily of a material adapted for p-type conduction and the other of each of said alternating layers being comprised primarily of a material adapted to provide an insulating barrier layer, each layer having a thickness of less than 20 nm,
2) a plurality of films comprised of electrical and thermal insulating material separating at least a portion of said quantum well films in said plurality of quantum well films from other quantum well films in said plurality of quantum well films,
wherein the quantum well film in each of the plurality of p-legs define a volume of quantum well film and the plurality of films of insulating material in each of the plurality of p-legs define a volume of insulating material and the ratio of the volume of insulating material to the volume of quantum well material is at least 12;
C) a plurality of electrical connector connecting said plurality of n-legs and p-legs in series.

2. The low cost quantum well thermoelectric module as in claim 1 wherein both the p-legs and the n-legs are comprised of super-lattice of silicon and silicon carbide.

3. The low cost quantum well thermoelectric module as in claim 1 wherein both the p-legs and the n-legs are comprised of super-lattice of boron and boron carbide.

4. The low cost quantum well thermoelectric module as in claim 1 wherein both the p-legs and the n-legs are comprised of materials chosen from one of the following group of material combinations:
A) crystalline silicon carbide and crystalline silicon,
B) amorphous silicon carbide and crystalline silicon,
C) amorphous silicon and crystalline silicon,
D) a crystalline polytype of silicon carbide and a different crystalline polytype of silicon carbide,
E) silicon nitride and silicon carbide,
F) aluminum nitride and silicon carbide,
G) boron nitride and silicon,
H) boron nitride and silicon carbide, and
I) boron nitride and silicon nitride.

6. The module as in claim 1 wherein the ratio of the volume of insulating material to the volume of quantum well material is at least 20.

7. The module as in claim 1 wherein the ratio of the volume of insulating material to the volume of quantum well material is at least 50.

8. The module as in claim 1 wherein the ratio of the volume of insulating material to the volume of quantum well material is at least 100.

9. The module as in claim 1 wherein the plurality of n-legs and p-legs are contained in a thermoelectric egg-crate.

10. The module as in claim 1 wherein each of the plurality of n-legs define a hot side and a cold side and both the hot side and cold side comprise implanted ions to improve electrical conductivity near the hot side and the cold side.

11. The module as in claim 1 wherein each of the plurality of p-legs define a hot side and a cold side and both the hot side and cold side comprise implanted ions to improve electrical conductivity near the hot side and the cold side.

12. The module as in claim 1 wherein the thicknesses of said super-lattice layers is about 10 nm.

13. The module as in claim 1 wherein the thicknesses of said super-lattice layers is about 4 nm.

14. The module as in claim 1 wherein the super-lattice layers are layers deposited on a substrate film.

15. The module as in claim 14 wherein the substrate film is a polyimide film.

16. The module as in claim 14 wherein the substrate film is a material chosen form the following group of materials: Mylar, polyethylene, NaCl, polyamide, polyamide-imides, polyimide compounds, oxide film, mica and glass sheet.

17. The module as in claim 1 wherein the insulator material is in the form of substrate material and spacer material.

18. The module as in claim 17 wherein the substrate material and the spacer material is a polyimide.

19. The module as in claim 2 wherein the silicon carbide in said alternating layers of p-type quantum well films is n-doped and the silicon in said alternating layers of p-type quantum well films is p-doped.

20. The module as in claim 2 wherein the silicon carbide in said alternating layers of p-type quantum well films is p-doped.

21. The module as in claim 3 wherein the p-legs are comprised of alternating super-lattice layers of B4C and B9C and the n-legs are comprised of at alternating super-lattice layers, at least one of the alternating layers being an n-doped polytype of boron carbide and the other layer being a different semiconductor.

22. The module as in claim 21 wherein the other layer is a different polytype of boron carbide.

23. The module as in claim 21 wherein the other layer is n-doped silicon.
